(19) United States
(12) Patent Application Publication
(10) Pub. No.: US 2012/0104360 A1
(43) Pub. Date: May 3, 2012

(54) STRAIN COMPENSATED SHORT-PERIOD SUPERLATTICES ON SEMIPOLAR OR NONPOLAR GAN FOR DEFECT REDUCTION AND STRESS ENGINEERING

(75) Inventors: Matthew T. Hardy, Goleta, CA (US); Steven P. DenBaars, Goleta, CA (US); James S. Speck, Goleta, CA (US); Shuji Nakamura, Santa Barbara, CA (US)

(73) Assignee: THE REGENTS OF THE UNIVERSITY OF CALIFORNIA, Oakland, CA (US)

(21) Appl. No.: 13/284,449

(22) Filed: Oct. 28, 2011

Related U.S. Application Data
(60) Provisional application No. 61/408,280, filed on Oct. 29, 2010.

(51) Int. Cl. H01L 29/15; H01L 21/20

(52) U.S. Cl. 257/18; 438/478; 257/E29.072; 257/E21.09

(57) ABSTRACT

An (AlInGaN) based semiconductor device, comprising a first layer that is a semipolar or nonpolar nitride (AlInGaN) layer having a lattice constant that is partially or fully relaxed, deposited on a substrate or a template, wherein there are one or more dislocations at a heterointerface between the first layer and the substrate or the template; one or more strain compensated layers on the first layer, for defect reduction and stress engineering in the device, that is lattice matched to a larger lattice constant of the first layer; and one or more nonpolar or semipolar (AlInGaN) device layers on the strain compensated layers.

### CROSS REFERENCE TO RELATED APPLICATIONS

This application claims the benefit under 35 U.S.C. Section 119(e) of co-pending and commonly-assigned U.S. Provisional Application Ser. No. 61/408,280 filed on Oct. 29, 2010, by Matthew T. Hardy, Steven P. DenBaars, James S. Speck, and Shuji Nakamura, entitled “STRAIN COMPENSATED SHORT-PERIOD SUPERLATTICES ON SEMIPOLAR GAN FOR DEFECT REDUCTION AND STRESS ENGINEERING,” attorney's docket number 30794.396-US-P1 (2011-203), which application is incorporated by reference herein.

This application is related to the following co-pending and commonly-assigned U.S. patent applications:

U.S. Utility application Ser. No. 12/661,652, filed on Aug. 23, 2010, by Hiroaki Ohta et. al., entitled “ANISOTROPIC STRAIN CONTROL IN SEMIPOLAR NITRIDE QUANTUM WELLS BY PARTIALLY OR FULLY RELAXED ALUMINUM INDIUM GALLIUM NITRIDE LAYERS WITH MISFIT DISLOCATIONS,” attorney's docket number 30794.318-US-U1 (2009-743-2), which application claims the benefit under 35 U.S.C. Section 119(e) of U.S. Provisional Application Ser. No. 61/236,059, filed on Aug. 21, 2009 by Hiroaki Ohta et. al., entitled “ANISOTROPIC STRAIN CONTROL IN SEMIPOLAR NITRIDE QUANTUM WELLS BY PARTIALLY OR FULLY RELAXED ALUMINUM INDIUM GALLIUM NITRIDE LAYERS WITH MISFIT DISLOCATIONS,” attorney's docket number 30794.318-US-P1 (2009-743-1); and

U.S. Utility application Ser. No. 12/861,532, filed on Aug. 23, 2010, by Hiroaki Ohta et. al., entitled “SEMIPOLAR NITRIDE-BASED DEVICES ON PARTIALLY OR FULLY RELAXED ALLOYS WITH MISFIT DISLOCATIONS AT THE HETEROINTERFACE,” attorney's docket number 30794.317-US-U1 (2009-742-2), which application claims the benefit under 35 U.S.C. Section 119(e) of U.S. Provisional Application Ser. No. 61/236,058, filed on Aug. 21, 2009, by Hiroaki Ohta et. al., entitled “SEMIPOLAR NITRIDE-BASED DEVICES ON PARTIALLY OR FULLY RELAXED ALLOYS WITH MISFIT DISLOCATIONS AT THE HETEROINTERFACE,” attorney's docket number 30794.317-US-P1 (2009-742-1);

which applications are incorporated by reference herein.

### BACKGROUND OF THE INVENTION

1. Field of the Invention

The present invention relates generally to Strain Compensated Short-Period Superlattices (SCSL) on semipolar GaN for defect reduction and stress engineering.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

Gallium Nitride (GaN) based Laser Diodes (LDs) have come a long way from their initial demonstration in 1996. Recently, green emitting LDs have been demonstrated on a c-plane and a semipolar (20-21) plane [2, 3]. However, threshold current densities (Jₜₕ) are still high relative to shorter wavelength devices, and output power is limited to 50 mW. To enhance both these properties, active region quality must be improved. Aside from phase segregation, one of the most significant challenges in growing the active regions for long wavelength devices is managing the strain for active regions with Indium (In) contents around 30%. One such approach is growing partially relaxed buffer layers beneath the active regions of the device. The relaxation changes the effective lattice constant of the underlying layer, reducing the strain in the active region.

In traditional, c-plane GaN growth, the primary slip system {0001}<11-20> is parallel to the growth plane, resulting in no shear stress on the slip plane. Without resolved shear strain, the dislocation glide mechanism used to relax buffer layers in other III-V systems is not available. Other relaxation mechanisms are available, but they result in a loss of planarity of the surface and massive degradation of the quality of the overgrown layers.

### SUMMARY OF THE INVENTION

To overcome the limitations in the prior art described above, and to overcome other limitations that will become apparent upon reading and understanding the present specification, the present invention discloses a III-nitride (AlInGaN) based semiconductor device, comprising a first layer that is a semipolar or nonpolar III-nitride (AlInGaN) layer having a lattice constant that is partially or fully relaxed, deposited on a substrate or template, wherein there are one or more dislocations at a heterointerface between the first layer and the substrate or the template; one or more strain compensated layers, such as a strain compensated short-period superlattice (SCSL), on the first layer, for defect reduction and stress engineering in the device; and one or more semipolar or nonpolar III-nitride (AlInGaN) device layers on the SCSL.

The first layer can be a buffer layer. The strain compensated layers can be lattice matched to a larger lattice constant of the first layer.

The SCSL can comprise alternating layers of InGaN and AlGaN, or one or more periods of GaN between InGaN and AlGaN. The strain compensated layers can have a material composition that has a refractive index less than a refractive index of GaN.

Each of the alternating layers, or each of the SCSL layers, can have a thickness below their critical thickness (e.g., Matthews-Blakeslee critical thickness h_{c}). A total thickness of the SCSL layers and the first layer can be more than 0.5 micrometers, or more than 1 micrometer.

The device layers can be LD device layers. A composition, thickness, and number of the alternating layers or SCSL layers can be sufficient to provide a waveguiding and/or cladding function for light emitted by an active layer in the LD.

In one example, the substrate is GaN, the first layer is InGaN, and the strain compensated layers and the first layer are under slight compressive strain. For example, in one embodiment, the average strain does not have to be zero—the average strain is small enough so that the full stack comprising the SCSL and the first layer does not relax. The tolerable strain can depend on the thickness and the substrate orientation. In one example, for a cladding layer with a typical thickness of 500 nm, the average strain would be less than 0.15% on a (20-21) GaN substrate, or less than 0.1% on a (11-22) GaN substrate. In another example, for waveguiding layers with a typical thickness of 50 nm, the strain would be less than about 1% on a GaN (20-21) substrate, or less than 0.5% on a (11-22) GaN substrate (these strain numbers are for twice the theoretical critical thickness, which is usually where relaxation is experimentally observed).

The device can be, but is not limited to, a light emitting diode (LED), solar cell, or an electronic device such as a transistor.

The present invention further discloses a method of fabricating a (AlInGaN) based semiconductor device, comprising growing a first layer that is a semipolar or nonpolar III-nitride (AlInGaN) layer having a lattice constant that is partially or fully relaxed, deposited on a substrate or a template, wherein there are one or more dislocations at a heterointerface between the first layer and the substrate or the template; growing one or more strain compensated layers on the first layer, lattice matched to a larger lattice constant of the first layer, for defect reduction and stress engineering in the device; and growing one or more (AlInGaN) nonpolar or semipolar device layers on the strain compensated layers.

### BRIEF DESCRIPTION OF THE DRAWINGS

Referring now to the drawings in which like reference numbers represent corresponding parts throughout:

FIGS. 1(a)-(d) show florescence images for samples including an In_{0.07}GaN buffer layer with the indicated thicknesses, wherein the sample in (a) has a 60 nanometer (nm) thick In_{0.07}GaN buffer layer, the sample in (b) has a 90 nm thick In_{0.07}GaN buffer layer, the sample in (c) has a 120 nm thick In_{0.07}GaN buffer layer, and the sample in (d) has a 150 nm thick In_{0.07}GaN buffer layer, the a-direction of III-nitride is indicated by the arrow (a-direction is the same in FIGS. 1(a)-(d)), and the scale is 15 micrometers (μm) in FIGS. 1(a)-(d).

FIG. 2 shows an Atomic Force Microscope (AFM) image of a sample including a 150 nm thick In_{0.07}GaN buffer layer, grown under the same conditions as the buffer layer in the sample labeled 100804CI (shown above in FIG. 1(d)), wherein the a-direction is indicated by the arrow labeled ‘a’.

FIGS. 3(a)-(b) show mono cathodoluminescence (CL) data collected at 385 nm (FIG. 3(a)) and 495 nm (FIG. 3(b)) for the sample labeled 100804CI (shown in above in FIG. 1(d)), wherein the a-direction is indicated by the arrow labeled ‘a’.

FIG. 4 is a contour plot plotting the log of critical thickness for various In and Aluminum (Al) compositions.

FIG. 5 is a graph/plot showing the average index for Transverse Electric (TE) waves in III-nitride material, plotted for Al compositions from 0% to 20% in steps of 2%, wherein the horizontal black line marks the index of GaN and is plotted as a reference.

FIG. 6 is an X-ray diffraction (XRD) ω-2θ scan of a 30 period In_{0.05}GaN/Al_{0.10}GaN SCSL, wherein the In_{0.05}GaN layers are each 5 nanometers (nm) thick, and the Al_{0.10}GaN layers are each 5 nm thick.

FIG. 7(a)-(c) show CL micrographs for Light Emitting Diode (LED) samples, wherein FIG. 7(a) is a CL micrograph of a relaxed InGaN buffer beneath the multi-quantum well (MQW) active region, FIG. 7(b) is a CL micrograph of a relaxed InGaN buffer followed by a 30 period (30×) In_{0.047}Ga_{0.953}N (5 nm thick)/Al_{0.12}Ga_{0.88}N strain-compensated superlattice (SCSL) beneath the MQW active region, and FIG. 7(c) a CL micrograph of a 50 period (50×) SCSL with the same structure as in FIG. 7(b).

FIG. 7(d) is a cross-sectional schematic of the LED structure measured in FIGS. 7(b)-(c).

FIG. 8 is a cross-sectional schematic of a device structure.

FIG. 9 is a flowchart illustrating a method of the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Nomenclature

GaN and its ternary and quaternary compounds incorporating aluminum and indium (AlGaN, InGaN, AlInGaN) are commonly referred to using the terms (Al,Ga,In)N, III-nitride, Group III-nitride, nitride, Al_{(1-x-y)}In_{y}GaₓN where 0<x<1 and 0<y<1, or AlInGaN, as used herein. All these terms are intended to be equivalent and broadly construed to include respective nitrides of the single species, Al, Ga, and In, as well as binary, ternary and quaternary compositions of such Group III metal species. Accordingly, these terms comprehend the compounds AlN, GaN, and InN, as well as the ternary compounds AlGaN, GaInN, and AlInN, and the quaternary compound AlGaInN, as species included in such nomenclature. When two or more of the (Ga, Al, In) component species are present, all possible compositions, including stoichiometric proportions as well as “off-stoichiometric” proportions (with respect to the relative mole fractions present of each of the (Ga, Al, In) component species that are present in the composition), can be employed within the broad scope of the invention. Accordingly, it will be appreciated that the discussion of the invention hereinafter in primary reference to GaN materials is applicable to the formation of various other (Al, Ga, In)N material species. Further, (Al,Ga,In)N materials within the scope of the invention may further include minor quantities of dopants and/or other impurity or inclusional materials. Boron (B) may also be included.

The term “AlₓGa₁₋ₓN-cladding-free” refers to the absence of waveguide cladding layers containing any mole fraction of Al, such as AlₓGa₁₋ₓN/GaN superlattices, bulk AlₓGa₁₋ₓN, or AlN. Other layers not used for optical guiding may contain some quantity of Al (e.g., less than 10% Al content). For example, an AlₓGa₁₋ₓN electron blocking layer may be present.

One approach to eliminating the spontaneous and piezoelectric polarization effects in GaN or III-nitride based optoelectronic devices is to grow the III-nitride devices on nonpolar planes of the crystal. Such planes contain equal numbers of Ga (or group III atoms) and N atoms and are charge-neutral. Furthermore, subsequent nonpolar layers are equivalent to one another so the bulk crystal will not be polarized along the growth direction. Two such families of symmetry-equivalent nonpolar planes in GaN are the {11-20} family, known collectively as a-planes, and the {1-100} family, known collectively as m-planes. Thus, nonpolar III-nitride is grown along a direction perpendicular to the (0001) c-axis of the III-nitride crystal.

Another approach to reducing polarization effects in (Ga,Al,In,B)N devices is to grow the devices on semi-polar planes of the crystal. The term “semi-polar plane” (also referred to as “semipolar plane”) can be used to refer to any plane that cannot be classified as c-plane, a-plane, or m-plane. In crystallographic terms, a semi-polar plane may include any plane that has at least two nonzero h, i, or k Miller indices and a nonzero l Miller index.

Technical Description

On semipolar growth planes, there is non-zero resolved shear stress on the basal plane, allowing dislocation glide to relax stress along the c-projection of the growth plane, while maintaining the planarity of the film [4]. The misfit dislocations created by glide are confined to the buffer layer/substrate interface. Provided the active region is sufficiently far away from the defected interface, say 2-3 times the dislocation core screening length, there will be little loss of carriers due to non-radiative recombination. However, initial work on partially relaxed InGaN buffers on (20-21) planes showed evidence of a secondary defect system, with some component that threaded through to the active region.

A series of samples were grown, the samples comprising a variable thickness In_{0.07}Ga_{0.93}N buffer layer (grown on a semipolar 20-21 GaN substrate), a 3 period (3×) In_{0.26}Ga_{0.74}N/GaN multi quantum well (MQW) active region on the buffer layer, and a 1 nm thick GaN cap on the active region.

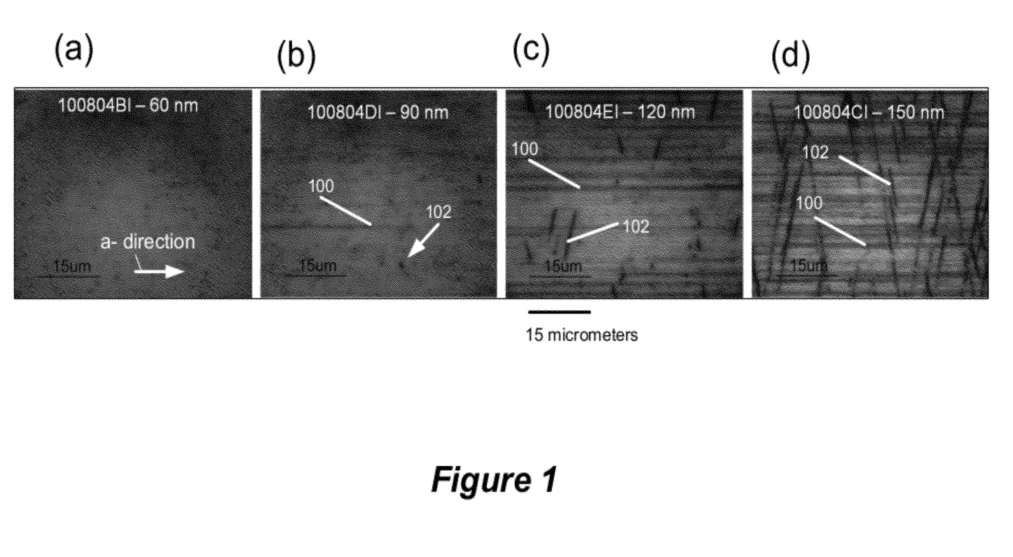

FIGS. 1(a)-(d) show the fluorescence micrographs for the above series of samples with the buffer layer thickness d=60, 90, 120 and 150 nm, respectively. With the onset of relaxation between 90 and 120 nm buffer layer thickness (FIGS. 1(b)-(d)), dark lines 100 appear parallel to the a-direction, as expected, corresponding to the dislocation line direction of misfit dislocations generated by glide on the c-plane.

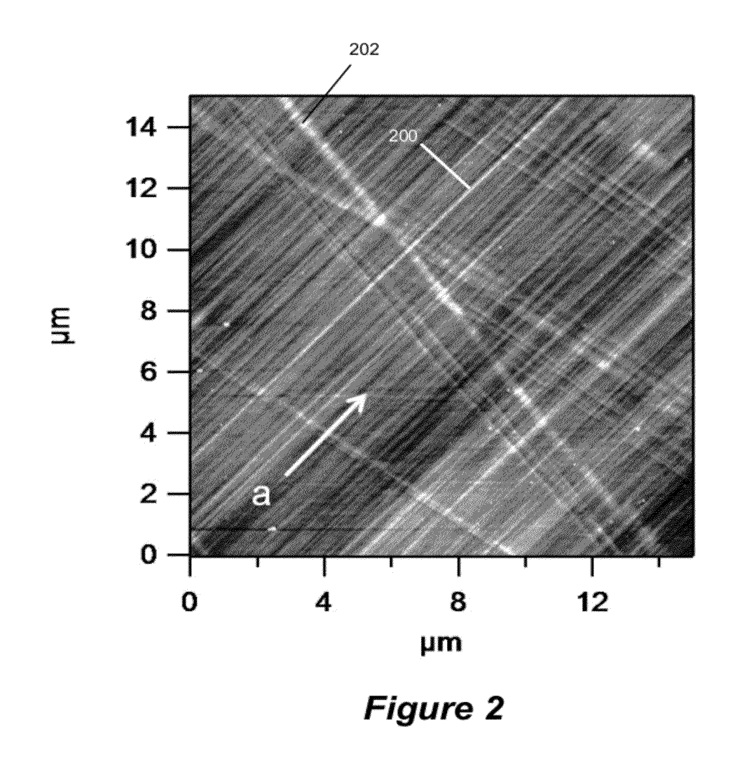

FIG. 2 shows AFM micrographs of a similar sample with only a 7% In composition, 150 nm thick InGaN buffer layer. Striations 200 can be seen in the a-direction, suggesting the a-direction lines in FIG. 1(b)-(d) may also be related to the quantum well (QW) surface morphology. Surprisingly, defects 102 also appear orientated about 20° off the in-plane projection of the c-axis, as shown in FIG. 1(b)-(d). These defects 102 seem to elongate with increasing thickness (and increasing degree of relaxation), suggesting glide on a secondary slip system. Angled features 202 with a similar orientation can also be seen in FIG. 2, indicating that these defects 202 may originate in the buffer layer.

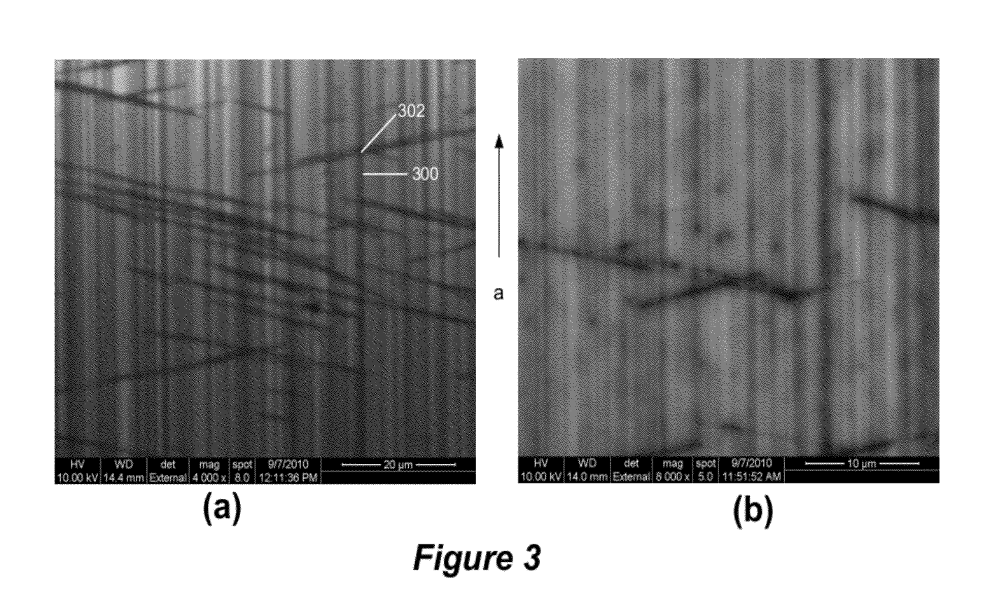

CL data shown in FIG. 3(a)-(b) for the sample of FIG. 1(d) confirms that these defects seen in FIGS. 1(b)-(d) and FIG. 2, and corresponding to defects 300, 302 in FIGS. 3(a)-(b), exist both in the underlying layer and in the MQW active region. Thus, a mechanism to reduce threading defects is necessary to reduce the defect 100, 102, 200, 202, 300, 302 density of the active region.

The defected region must be spatially separated at least 100-200 nm from the active region to prevent the charged dislocation cores from drawing carriers out of the active region, where they combine non-radiatively. In terms of LD design, this precludes the use of the relaxed buffer as a waveguiding layer, and requires the buffer layer to be placed below the n-cladding layer. This places an additional design constraint on the n-cladding layer. The n-cladding layer must have a sufficiently low refractive index (hereinafter referred to as “index”), and large thickness, to keep the mode out of the parasitic InGaN waveguide. Additionally, the design space in terms of critical thickness becomes sharply limited by the larger, relaxed lattice constant of the underlying layer.

Ternary AlInN cladding [4], or quaternary AlInGaN cladding [5], and InGaN/AlGaN SCSLs can be used to meet the above requirements, having an index lower than that of GaN, while still being lattice matched to the larger lattice constant of the relaxed buffer layer. Only SCSLs can reduce threading dislocations through dislocation reactions or bending along the interface [1].

InGaN/GaN/AlGaN SCSLs have been demonstrated on c-plane, however there are no reports of defect reduction. On c-plane, glide mechanisms are not active (as mentioned above), so defect reductions mentioned in [1] may not be active. Also, the large inclination angle of c-plane threading dislocations relative to the growth plane may lead to enhanced dislocation reduction through dislocation bending.

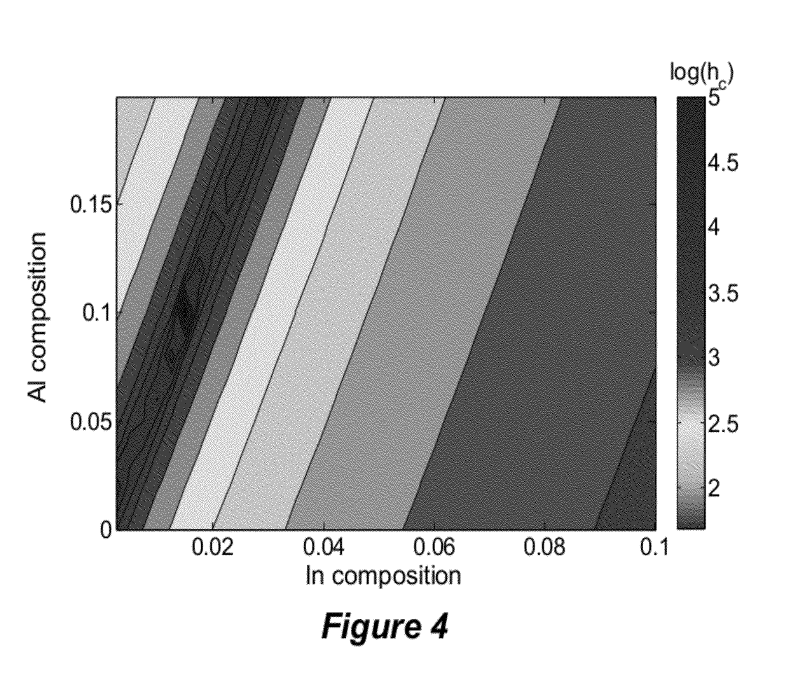

While total strain energy still accumulates in a SCSL, the misfit strain energy is determined by the average lattice constant of the superlattice (SL). FIG. 4 shows a map of Matthews-Blakeslee critical thickness (h_{c}), as a function of Aluminum (Al) and Indium (In) content in a structure with equal InGaN and AlGaN thicknesses. So long as the individual layers are below their respective h_{c}, the SCSL will not relax by dislocation glide unless h_{c} is exceeded. In reality, kinetic barriers to dislocation glide will cause the effective h_{c} to be greater than the thermodynamic Matthews-Blakeslee critical thickness.

The average index for the entire SCSL structure comprising two types of layer, layer 1 and layer 2, for TE polarized waves, can be calculated according to:

$${n}^{2} = \frac{{n}_{1}^{2} \times {N}_{1} \times {d}_{1} + {n}_{2}^{2} \times {N}_{2} \times {d}_{2}}{{N}_{1} \times {d}_{1} + {N}_{2} \times {d}_{2}} \qquad ( 1 )$$

where n₁ and n₂ are the indexes of layer 1 and layer 2 in each period, respectively, N₁ is the number of layer 1 in the structure, N₂ is the number of layer 2 in the structure, and d₁ and d₂ are the thicknesses of layer 1 and layer 2, respectively.

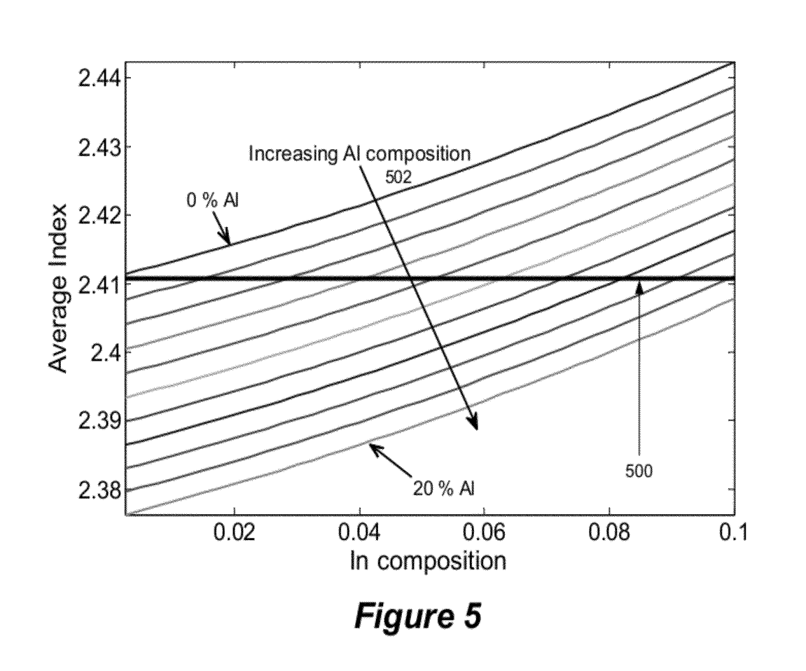

FIG. 5 gives the average index of the SCSL as a function of In content for different AlGaN concentrations, wherein the index of GaN is also plotted as a reference (indicated by the horizontal black line 500), and the arrow 502 indicates the direction of increasing Aluminum (Al) composition in the graph. From FIGS. 4 and 5, there is a large design space available, with average index less than that of GaN and with high critical thickness, much in excess of the 0.5-1 μm typically used for n-cladding in GaN based LDs.

The present invention enables growth of an optimized structure on a defected buffer layer, and shows defect reduction by CL and X-ray diffraction (XRD), although transmission electron microscopy (TEM) or etch pit density measurements can also be used to show defect reduction, for example.

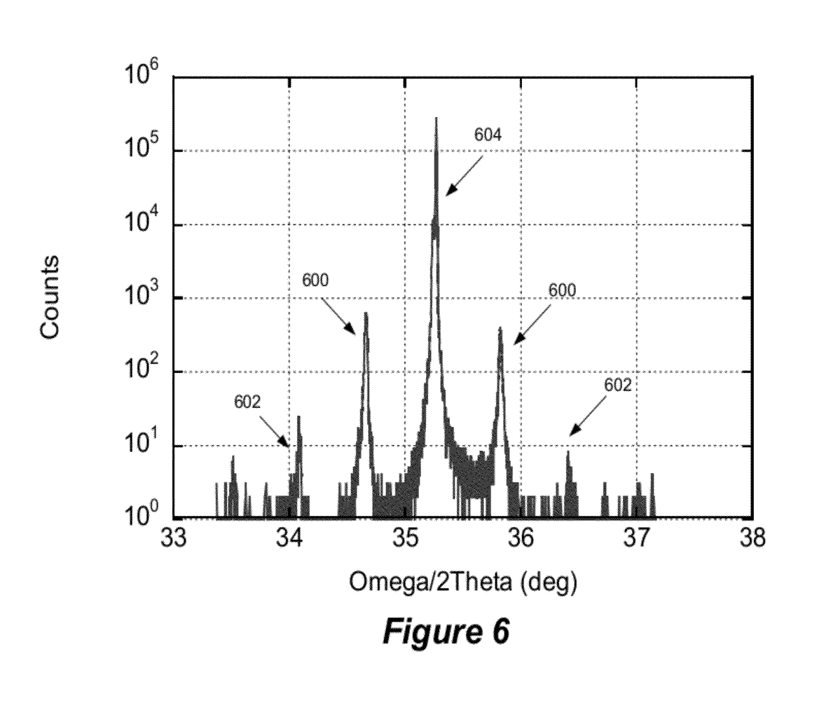

Initial SCSL growths were done using 30 periods of alternating In_{0.05}GaN/Al_{0.10}GaN layers, wherein each InGaN layer and each AlGaN layer is 5 nm thick. FIG. 6 shows an on-axis ω-2θ scan of such an SCSL. The superlattice (SL) SL±1 peak 600 and SL±2 peak 602 are clearly visible, indicating good structural quality. The 0^{th} order SL peak 604 is just to the low angle side of the GaN substrate peak, indicating slight compressive strain in the system—which is ideal for lattice matching to a relaxed InGaN buffer.

To examine the potential for defect reduction in the SCSL, a series of samples with varying numbers of superlattice period were grown and measured using CL.

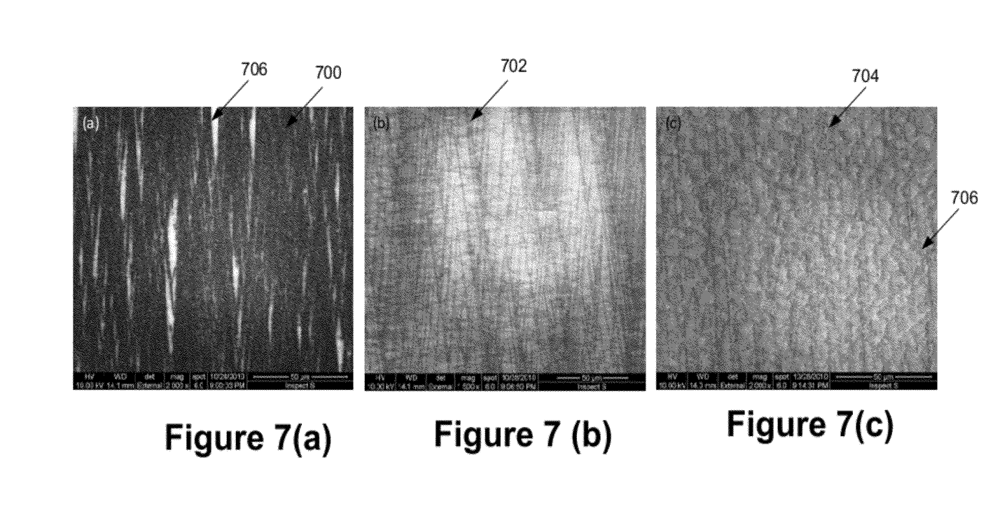

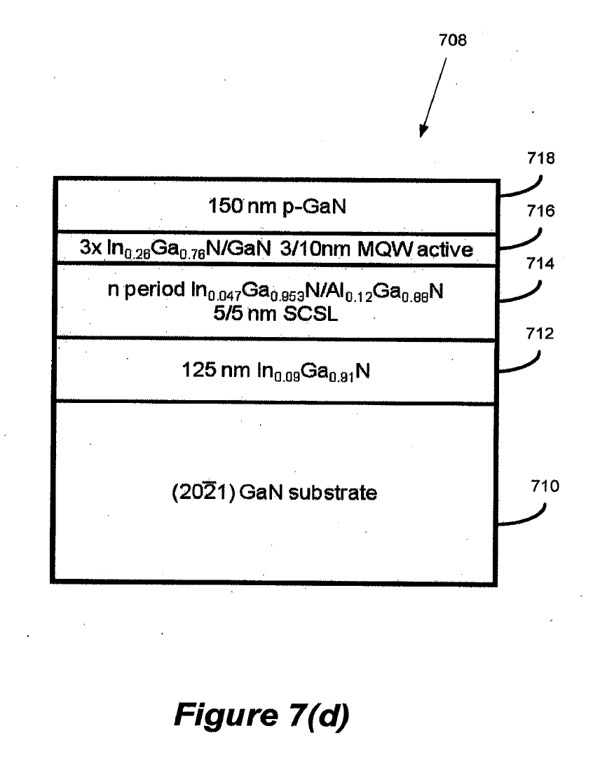

FIGS. 7(a)-(c) show CL micrographs for LED samples with a 130 nm thick In_{0.09}Ga_{0.91}N partially relaxed buffer layer. The sample shown in FIG. 7(a) had no SCSL, while FIG. 7(b) and FIG. 7(c) show samples with a 30 period (30×) and 50 period (50×) SCSL, respectively. The SCSL in the samples of FIG. 7(b) and FIG. 7(c) comprise In_{0.047}Ga_{0.953}N/Al_{0.12}Ga_{0.88}N layers wherein the In_{0.047}Ga_{0.953}N layers are each 5 nm thick and the Al_{0.12}Ga_{0.88}N layers are each 5 nm thick.

As seen in FIG. 7(a), large numbers of defects are formed in the relaxed buffer and propagate into the active region, causing dense, dark spots 700 in the CL image. For a 30× SCSL (FIG. 7(b)), the density of dark defects 702 is greatly reduced, and for the sample with a 50× SCSL (FIG. 7(c)), the dark defects 704 have become very sparse and the majority of the image is free these angled defects. This suggests the SCSL effectively prevents defects generated in the buffer from propagating up into the active region. The luminescence of the LED is shown by bright areas 706.

FIG. 7(d) is a cross-sectional schematic of the LED structure 708 measured in FIGS. 7(b)-7(c), comprising a (20-21) GaN substrate 710, a 125 nm thick In_{0.09}Ga_{0.91}N layer 712 on or above the (20-21) GaN substrate 710, and an n-period (n=30) In_{0.047}Ga_{0.953}N/Al_{0.12}Ga_{0.88}N SCSL 714 on or above the In_{0.09}Ga_{0.91}N layer 712 layer. The SCSL's 714 In_{0.047}Ga_{0.953}N layer is 5 nanometers (nm) thick and the SCSL's 714 Al_{0.12}Ga_{0.88}N layer is 5 nm thick. A multi-quantum-well (MQW) active layer 716 is on or above the SCSL 714. The active layer 716 comprises a 3 period In_{0.28}Ga_{0.76}N/GaN MQW, wherein the In_{0.28}Ga_{0.76}N layer is 3 nm thick and the GaN layer is 10 nm thick. A 150 nm thick p-type GaN layer 718 is on or above the active layer 714.

FIG. 7(a) measured a similar structure without the SCSL 712.

The structure is nominally lattice matched to the relaxed buffer and does not show tensile relaxation as verified by a reciprocal space map.

Growth Conditions

All samples were grown using atmospheric pressure Metal Organic Chemical Vapor Deposition (MOCVD) with trimethylgallium (TMG), triethylgallium (TEG), trimethylindium (TMI), trimethylaluminium (TMA) as the group III precursors and ammonia (NH₃) as the group V precursor. The GaN template is typically grown at a thermocouple couple temperature greater than 1100° C. with V-III ratios greater than 2000. The InGaN buffer layer and InGaN/AlGaN SCSL temperature is determined by the InGaN composition required, and for our growth rates of ˜5 nm/minute the thermocouple temperatures were typically between 880° C. and 940° C., with V-III ratios greater than 10 000. In this case the AlGaN was not grown at temperatures higher than the InGaN in the SCSL. Thermocouple temperatures can be as much as 100° C. above the actual substrate surface temperature.

Note however, these growth parameters are merely provided as an example. Other growth conditions and growth methods, such as, but not limited to, Molecular Beam Epitaxy (MBE), Hydride Vapor Phase Epitaxy (HVPE), Vapor Phase Epitaxy, etc., can also be used.

Device Structure

Substrate, First Layer, and Strain Compensated Layers

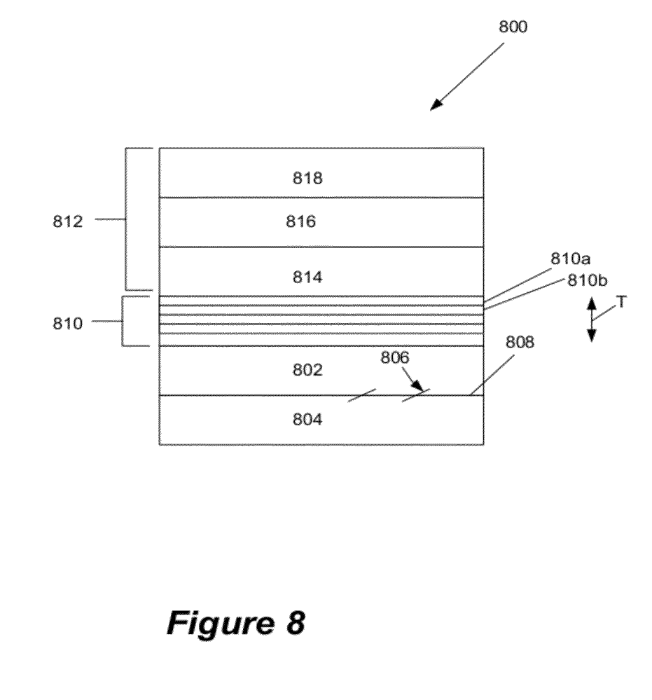

FIG. 8 illustrates a III-nitride (e.g., AlInGaN) based semiconductor device 800, comprising a first layer 802 deposited on a substrate 804 or a template.

The substrate 804 can be bulk III-nitride or a film of III-nitride (e.g., semipolar or nonpolar). The substrate can comprise an initial non-polar or semi-polar III-nitride template layer or epilayer grown on a substrate (e.g., heteroepitaxially on a foreign substrate, such as sapphire or silicon carbide, or spinel).

The first layer 802 can be a semipolar or nonpolar III-nitride layer. The first layer can have a lattice constant that is partially or fully relaxed, wherein there are one or more dislocations 806 at a heterointerface 808 between the first layer 802 and the substrate 802 or the template. The first layer can be a buffer layer, for example.

One or more strain compensated layers 810 (e.g., III-nitride semipolar or nonpolar layers) are deposited on the first layer 802, for defect reduction and stress engineering in the device. The strain compensated layers 810 are lattice matched to a larger lattice constant of the first layer and comprise layers 810a and 810b.

The strain compensated layers 810 can comprise a short-period superlattice (SCSL). For example, the SCSL can comprise alternating layers of InGaN 810a and AlGaN 810b. Alternatively, the SCSL layers 810a, 810b can comprise one or more periods of GaN between InGaN and AlGaN. Each of the alternating layers 810a, 810b, or each of the layers 810a, 810b in the SCSL, can have a thickness below their critical thickness.

The equilibrium critical thickness corresponds to the case when it is energetically favorable to form one misfit dislocation at the layer/substrate interface.

Experimental, or kinetic critical thickness, is always somewhat or significantly larger than the equilibrium critical thickness. However, regardless of whether the critical thickness is the equilibrium or kinetic critical thickness, the critical thickness corresponds to the thickness where a layer transforms from fully coherent to partially relaxed.

Another example of the critical thickness is the Matthews Blakeslee critical thickness h_{c} [1].

The average lattice constant of the SCSL 810 can be engineered to match either a normal GaN substrate 804, or if a relaxed buffer layer 802 is grown, it can be designed to match the buffer layer 802. If a relaxed InGaN buffer layer 802 is grown, the lattice constant will increase. In this case an SCSL 810 with more InGaN and/or less AlGaN can be designed to lattice match to the InGaN buffer layer 802 (or at least come close enough).

Strain compensated means that the two alternating layers 810a, 810b of the superlattice (SL) have roughly equal but opposite strain, i.e., an InGaN/AlGaN stack where the composition and thickness of the InGaN 810a has the same strain energy (in the opposite sense) as the AlGaN 810b. The composition and thicknesses of the two layers 810a, 810b can be designed to lattice match to GaN (i.e., have no strain relative to GaN), or to lattice match to the InGaN buffer layer 802 (which could, due to relaxation, have a larger lattice constant than GaN).

A composition, thickness, and number of the alternating layers 810a, 810b or SCSL layers 810a, 810b can be sufficient to provide a waveguiding and/or cladding function for light emitted by an active layer in a laser diode. A total thickness T of the SCSL layers 810, 810a, 810b and the first layer 802 can be more than 0.5 micrometers, or more than 1 micrometer. The strain compensated layers 810 can have a material composition that has a refractive index that is less than a refractive index of GaN.

For example, Indium (In) content in the SCSL 810 could be 5-20%, and the Aluminum (Al) content in the AlGaN 810b of the SCSL 810 could be 5-40%. GaN could be used instead of the AlGaN (if it is grown on a relaxed InGaN buffer 802).

The AlGaN layer 810b of the SCSL 810 is typically less than 3 nm thick and more than 1 nm thick, and the InGaN layer 810a of the SCSL 810 is typically less than 10 nm thick, and more than 1 nm thick.

However, the present invention is not limited to these compositions and thicknesses.

In one example, the substrate 804 is GaN, the first layer 802 is InGaN, and the strain compensated layers 810 and the first layer 802 are under slight compressive strain.

For example, in one embodiment, the average strain does not have to be zero—the average strain is small enough so that the full stack comprising the SCSL 810 and the first layer 802 does not relax. The tolerable strain depends on the thickness and the substrate 804 orientation. In one example, for an SCSL 810 comprising a cladding layer 810 with a typical thickness T of 500 nm, the average strain would be less than 0.15% on a (20-21) GaN substrate 804, or less than 0.1% on a (11-22) GaN substrate 804. In another example, for and SCSL comprising waveguiding layers 810 with a typical thickness T of 50 nm, the strain would be less than about 1% on a GaN (20-21) substrate 804, or less than 0.5% on a (11-22) GaN substrate 804 (these strain numbers are for twice the theoretical critical thickness, which is usually where relaxation is experimentally observed). However, the present invention is not limited to these strain numbers (which are provided as examples), and other strain numbers (e.g., for theoretical critical thickness) can also be used.

The first layer 802 and/or SCSL 810 can also have zero strain, for example.

Additional Device Layers

FIG. 8 shows one or more III-nitride device layers 812 (e.g., semipolar or nonpolar III-nitride layers) are (e.g., deposited or grown) on the strain compensated layers 810.

The device layers 812 can be LD device layers. For example, the strain compensated layers 810 can be n-type waveguide and cladding layers, and the device layers 812 can further comprise a semi-polar III-nitride light emitting active layer 814 deposited on the strain compensated layers 810, an AlGaN electron blocking layer 816 deposited on the active layer 814, a p-type layer 818, such as a waveguide and/or cladding layers 818, deposited on the electron blocking layer 816, and a GaN layer 820 on the p-type layer 818 (e.g., waveguide and/or cladding layers 818). If layers 810 are p-type, then layer 818 can be n-type, or of opposite polarity to the layers 810, for example).

The semi-polar III-nitride active layer 814 can comprise one or more semi-polar light emitting Indium containing active layers, wherein the active layer(s) emit light having a peak intensity at a wavelength in a green wavelength range or longer (e.g. yellow or red light), or a peak intensity at a wavelength of 500 nm or longer. However, the present invention is not limited to devices 800 emitting at these wavelengths. For example, the present invention can be used to fabricate blue light or ultraviolet light emitting devices, for example. The active layers 814 can be sufficiently thick and have sufficiently high Indium composition such that the light emitting device 800 emits the light having the desired wavelengths.

The light emitting active layer(s) 814 can include InGaN layers, e.g., one or more InGaN quantum wells with GaN barriers. The InGaN quantum wells can have an Indium composition of at least 7%, at least 10%, or at least 16%, or at least 30%, and a thickness greater than 4 nanometers (e.g., 5 nm), at least 5 nm, or at least 8 nm, for example. However, the quantum well thickness may also be less than 4 nm, although it is typically above 2 nm thickness.

The waveguiding layers 818 can comprise indium containing layers such as one or more InGaN quantum wells with GaN barrier layers (e.g., Indium content of at least 30%). The cladding layers 818 can comprise one or more periods of alternating AlGaN and GaN layers, for example. However, the device structure 800 can be AlGaN cladding layer free.

The semi-polar III-nitride device layers 814 can comprise layers that are coherently grown, non-coherently grown, or that are partially or fully relaxed. For a layer X grown on a layer Y, for the case of coherent growth, the in-plane lattice constant(s) of X are constrained to be the same as the underlying layer Y. If X is fully relaxed, then the lattice constants of X assume their natural (i.e. in the absence of any strain) value. If X is neither coherent nor fully relaxed with respect to Y, then it is considered to be partially relaxed. In some cases, the substrate might have some residual strain.

FIG. 8 can also illustrate a Light Emitting Diode structure 800, comprising, for example, an n-type layer 810, active layer 814, electron blocking layer 816, p-type GaN layer 818, and GaN layer 820. Layers can be added or omitted as desired. Non-polar (e.g., a-plane or m-plane) devices or semi-polar devices can be fabricated, for example.

Process Steps

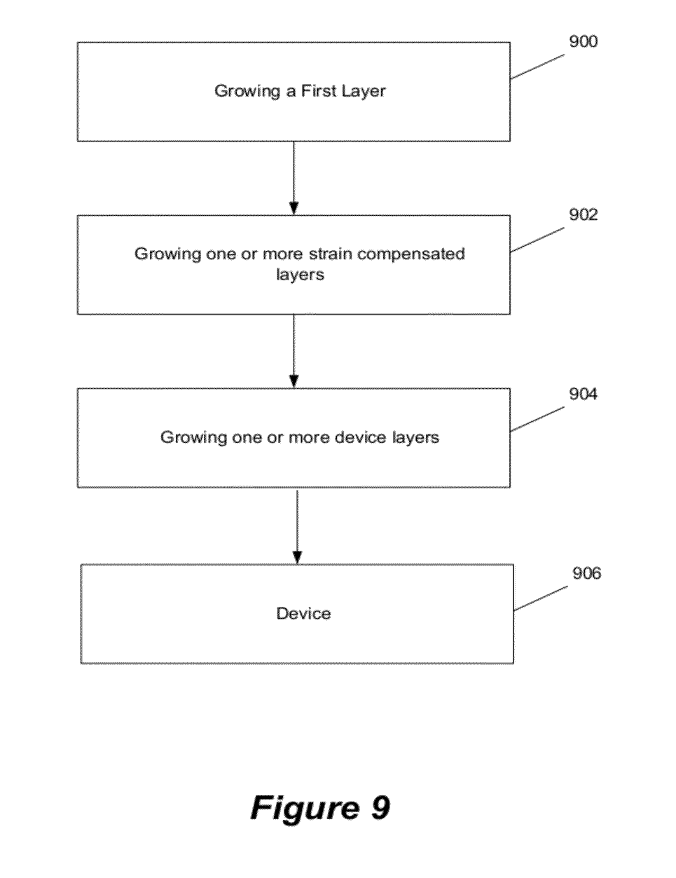

FIG. 9 illustrates a method of fabricating a (AlInGaN) based semiconductor device, comprising the following steps.

Block 900 represents growing/depositing a first layer on a substrate or a template. The first layer can be a semipolar III-nitride (AlInGaN) layer. The first layer can have a lattice constant that is partially or fully relaxed, wherein there are one or more dislocations at a heterointerface between the first layer and the substrate or the template.

Block 902 represents growing one or more strain compensated layers (e.g., semipolar III-nitride layers) on the first layer, lattice matched to a larger lattice constant of the first layer, for defect reduction and stress engineering in the device.

Block 904 represents growing one or more (AlInGaN) or III-nitride semipolar device layers on the strain compensated layers.

Block 906 represents the end result, a device 800 that can be an optoelectronic device, a light emitting diode, laser diode (LD), solar cell, or an electronic device such as a transistor or High Electron Mobility Transistor (HEMT), for example.

Steps can be added or omitted as desired.

Advantages and Improvements

The present invention can achieve higher efficiency light emitting devices (e.g., light emitting diodes (LEDs), Laser Diodes (LDs)), especially when combined with partially or completely relaxed buffer layers.

For LEDs, a strain compensated superlattice (SCSL) can help preserve the benefits of relaxed buffer layers in reducing active region strain. The same benefit applies to LDs, where SCSLs can also be used to act as a cladding layer with a refractive index lower than that of GaN, while still being nearly lattice matched to the underlying layer. This is especially critical for long wavelength LDs. In such devices, a larger effective lattice constant is desirable as a result of the buffer layer relaxation. This would increase the tensile strain in traditional AlGaN or AlGaN/GaN strained superlattices (SLs) and decrease the maximum thickness and/or composition of such a layer before the onset of relaxation. This would lead to decreased confinement of the optical mode and higher threshold current densities. This can be avoided with AlInN or AlInGaN cladding, but these “bulk” layers have no way of reducing defect propagation, while SCSLs have been shown in other material systems to reduce threading defect concentrations [1].

### REFERENCES

The following references are incorporated by reference herein.

[1] J. Matthews and A. Blakeslee, J. Cryst. Growth 32 265 (1976).

[2] A. Avramescu, T. Lermer, J. Müller, C. Eichler, G. Bruederl, M. Sabathil, S. Lutgen and U. Strauss, Appl. Phys. Express 3 061003 (2010).

[3] M. Ueno, Y. Yoshizumi, Y. Enya, T. Kyono, M. Adachi, S. Takagi, S. Tokuyama, T. Sumitomo, K. Sumiyoshi, N. Saga, T. Ikegami, K. Katayama and T. Nakamura, J. Cryst. Growth Article in press, doi:10.1016/j.jcrysgro.2010.07.016 (2010).

[4] A. Tyagi, F. Wu, E. C. Young, A. Chakraborty, H. Ohta, R. Bhat, K. Fujito, S. P. DenBaars, S. Nakamura and J. S. Speck, Appl. Phys. Lett. 95 251905 (2009).

[5] A. Castiglia, E. Feltin, G Cosendey, A. Altoukhov, J.-F. Carlin, R, Butte and N. Grandjean, Appl. Phys. Lett. 94 193506 (2009).

[6] Y. Yoshizumi, M. Adachi, Y. Enya, T. Kyono, S. Tokuyama, T. Sumitomo, K, Akita, T. Ikegami, M. Ueno, K. Katayama, and T. Nakamura, Appl. Phys. Express 2 092101 (2009).

Conclusion

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A III-nitride based semiconductor device, comprising:
a first layer that is a semipolar or nonpolar III-nitride layer having a lattice constant that is partially or fully relaxed, deposited on a substrate or a template, wherein there are one or more dislocations at a heterointerface between the first layer and the substrate or the template;
one or more strain compensated layers on the first layer, for defect reduction and stress engineering in the device, that are lattice matched to a larger lattice constant of the first layer; and
one or more semipolar or nonpolar (AlInGaN) or III-nitride device layers on the strain compensated layers.

2. The device of claim 1, where the strain compensated layers comprise a short-period superlattice (SCSL).

3. The device of claim 2, wherein the SCSL comprises alternating layers of InGaN and AlGaN, or SCSL layers comprising one or more periods of GaN between InGaN and AlGaN.

4. The device of claim 3, wherein the each of the alternating layers, or each of the SCSL layers, has a thickness below their Matthews-Blakeslee critical thickness h_{c}.

5. The device of claim 4, wherein the device layers are laser diode device layers.

6. The device of claim 4, wherein a composition, thickness, and number of the alternating layers or SCSL layers is sufficient to provide one or more of a waveguiding or cladding function for light emitted by an active layer in the laser diode.

7. The device of claim 6, wherein a total thickness of the SCSL layers and the first layer is more than 0.5 micrometers or more than 1 micrometer.

8. The device of claim 1, wherein the substrate is GaN, the first layer is InGaN, and the strain compensated layers and the first layer are under slight compressive strain.

9. The device of claim 1, wherein the strain compensated layers have a material composition that has a refractive index less than a refractive index of GaN.

10. The device of claim 1, wherein the device is a light emitting diode or an electronic device including a transistor.

11. The device of claim 1, wherein the first layer is a buffer layer.

12. A method of fabricating a (AlInGaN) or III-nitride based semiconductor device, comprising:
growing a first layer that is a semipolar or nonpolar III-nitride (AlInGaN) layer having a lattice constant that is partially or fully relaxed, on a substrate or a template, wherein there are one or more dislocations at a heterointerface between the first layer and the substrate or the template;
growing one or more strain compensated layers on the first layer, lattice matched to a larger lattice constant of the first layer, for defect reduction and stress engineering in the device; and
growing one or more semipolar or nonpolar (AlInGaN) or III-nitride device layers on the strain compensated layers.

13. The method of claim 12, where the strained compensated layers comprise a short-period superlattice (SCSL).

14. The method of claim 13, wherein the SCSL comprises alternating layers of InGaN and AlGaN, or SCSL layers comprising one or more periods of GaN between InGaN and AlGaN.

15. The method of claim 14, wherein the each of the alternating layers, or each of the SCSL layers, has a thickness below their Matthews-Blakeslee critical thickness h_{c}.

16. The method of claim 15, wherein the device layers are laser diode device layers.

17. The method of claim 16, wherein a composition, thickness, and number of the alternating layers or SCSL layers is sufficient to provide one or more of a waveguiding or cladding function for light emitted by an active layer in the laser diode.

18. The device of claim 17, wherein a total thickness of the SCSL layers and the first layer is more than 0.5 micrometers or more than 1 micrometer.

19. The method of claim 12, wherein the substrate is GaN, the first layer is InGaN, and the strain compensated layers and the first layer are under slight compressive strain.

20. The method of claim 12, wherein the a strain compensated layers have a material composition that has a refractive index less than a refractive index of GaN.

21. The method of claim 12, wherein the device is a light emitting diode or an electronic device including a transistor.

22. The method of claim 12 wherein the first layer is a buffer layer.
